(19) United States
(12) Patent Application Publication
(10) Pub. No.: US 2016/0099204 A1
(43) Pub. Date: Apr. 7, 2016

(54) PACKAGE SUBSTRATE, PACKAGE STRUCTURE, AND METHODS OF FABRICATING THE SAME

(71) Applicant: Siliconware Precision Industries Co., Ltd., Taichung (TW)

(72) Inventors: Chang-Fu Lin, Taichung (TW); Chin-Tsai Yao, Taichung (TW); Chia-Cheng Chen, Taichung (TW); Chih-Jen Yang, Taichung (TW); Fu-Tang Huang, Taichung (TW)

(21) Appl. No.: 14/709,510

(22) Filed: May 12, 2015

(30) Foreign Application Priority Data
Oct. 3, 2014 (TW) 103134528

(51) Int. Cl. H01L 23/498; H01L 21/56; H01L 23/00; H01L 23/31; H05K 1/11; H01L 21/48

(52) U.S. Cl. CPC H01L 23/49838; H05K 1/111; H01L 21/4846; H01L 24/17; H01L 24/81; H01L 23/3107; H01L 21/56; H05K 2201/09227; H05K 2201/09654; H01L 2224/16227; H01L 2224/81191

(57) ABSTRACT

A package structure is provided, including: a board having a plurality of conductive traces; a plurality of conductive pads formed on the board and each having a height greater than a height of each of the conductive traces; and an electronic component disposed on and electrically connected to the conductive pads via a plurality of conductive elements, wherein at least one of the conductive traces is positioned in proximity of at least one of the conductive pads. Therefore, the conductive elements are prevented from being in contact with the conductive traces, and the problem that the conductive pads and the conductive traces are shorted is solved. The present invention further provides a method for fabricating the packaging substrate.

### BACKGROUND OF THE INVENTION

1. Field of the Invention

The present invention relates to package substrates, and, more particularly, to a package substrate having a high yield rate and a method of fabricating the same.

2. Description of Related Art

With the advancement in electronic industry, the demand for electronic products with light weight, low-profile and high functionality is increasing. Flip-chip technology is thus developed in order to meet the requirements for high integration, miniaturization and high functionality.

As shown in FIGS. 1 and 1′, a package structure 1 of a conventional flip-chip type comprises a substrate 10 having a plurality of conductive traces 11 and a plurality of conductive pads 13, a chip 16 disposed on the conductive pads 13 via a plurality of conductive bumps 15, and an encapsulant 17 that encapsulates the chip 16. The height d of the conductive pads 13 is equal to the height d of the conductive traces 11.

Due to the ever decreasing size of the package structure and the popular trend of miniaturization, the pitch between the contact points has become smaller For instance, the width of the conductive pads 13 is less than 75 um, and the width and pitch of the conductive traces 11 are 15 um.

However, in the conventional package structure 1, as the height d of the conductive pads 13 is equal to the height d of the conductive traces 11, that is, the path L from the top surface of the conductive pads 13 to the top surfaces of the conductive traces 11 appears to be a horizontal path of 15 μm, it is highly likely that the conductive bumps 15 make contact with the conductive traces 11 besides the conductive pads 13, resulting in short circuit and low yield.

Thus, there is an urgent need for providing the aforementioned problems in the prior art.

### SUMMARY OF THE INVENTION

In view of the aforementioned drawbacks, the present invention provides a package structure, comprising: a package substrate, comprising: a board having a plurality of conductive traces; a plurality of conductive pads formed on the board and each having a height greater than a height of each of the conductive traces; and an electronic component disposed on and electrically connected to the conductive pads via a plurality of conductive elements, wherein at least one of the conductive traces is positioned in proximity of at least one of the conductive pads.

The present invention further provides a method of fabricating a package structure, comprising: forming a plurality of conductive pads on a board that has a plurality of conductive traces, wherein each of the conductive pads has a height greater than a height of each of the conductive traces, and at least one of the conductive traces is positioned in proximity of at least one of the conductive pads; and disposing an electronic component on the conductive pads, and electrically connecting the electronic component to the conductive pads via a plurality of conductive elements.

In an embodiment, the surface of each of the conductive traces is flush with or lower than the surface of the board.

In an embodiment, the surface of each of the conductive traces is exposed from the surface of the board.

In an embodiment, the conductive pads are formed on the conductive traces. For instance, more than one of the conductive pads are formed on one of the conductive traces.

In an embodiment, the method further comprises forming an insulating protection layer on the board, with the conductive pads exposed from the insulating protection layer.

In an embodiment, the method further comprises forming on the board an encapsulating layer that encapsulates the electronic component.

In summary, the package structure and the fabricating method thereof according to the present invention are characterized by making the height of each of the conductive pads to be greater than the height of each of the conductive traces, such that when the electronic component is disposed on each of the conductive pads, the conductive elements are prevented from making contact with the conductive traces, thereby preventing short circuit from occurrence.

### BRIEF DESCRIPTION OF DRAWINGS

FIG. 1 is a schematic cross-sectional view showing a conventional package structure;

FIG. 1′ is a partial, enlarged view of FIG. 1;

FIGS. 2A-2C are schematic cross-sectional views illustrating a method of fabricating a package substrate according to the present invention, wherein FIGS. 2B′, 2C′ and 2C″ show another embodiment of FIGS. 2B and 2C;

FIG. 3 is a cross-sectional view showing a package structure according to the present invention; FIG. 3′ is a top view of the package substrates according to the present invention, wherein A-A cross-sectional line defines the cross-sectional view of FIG. 3; FIG. 3″ is a partial, enlarged view of FIG. 3;

FIG. 4A is a top view showing a package substrate in accordance with another embodiment of the present invention;

FIG. 4B is a schematic cross-sectional view of FIG. 4A with line B-B as the cross-sectional line;

FIG. 4C is a schematic cross-sectional view of FIG. 4A with line C-C as the cross-sectional line;

FIG. 5A is a top view showing a package substrate in accordance with another embodiment of the present invention; and

FIG. 5B is a schematic cross-sectional view of FIG. 5A with the line D-D as the cross-sectional line.

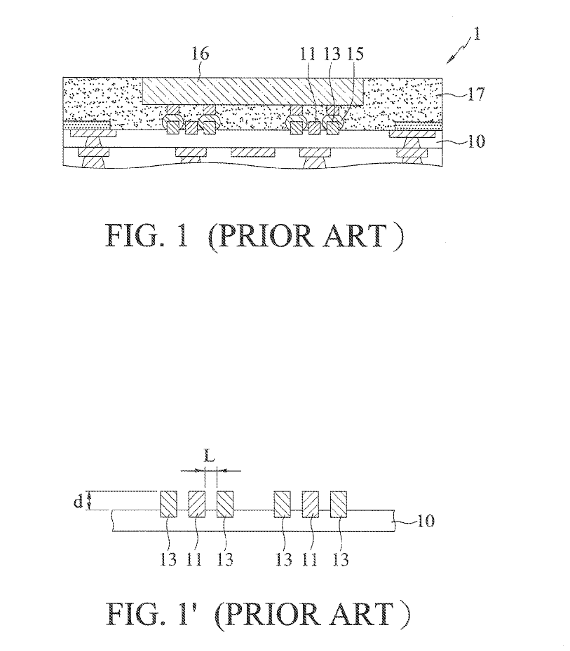

### DETAILED DESCRIPTION OF PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “on”, “first”, “second”, and “one” etc., are merely for illustrative purpose and should not be construed to limit the scope of the present invention.

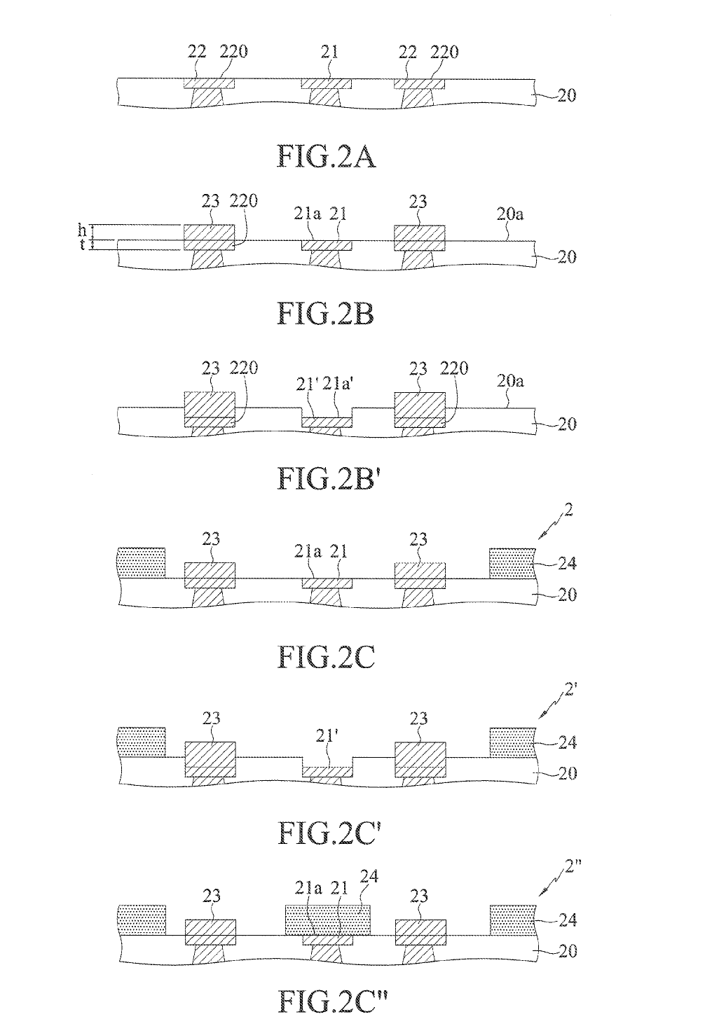

FIG. 2A-2C are cross-sectional views showing a method of fabricating a package substrates 2, 2′ according to the present invention.

As shown in FIG. 2A, a board 20 having a plurality of first conductive traces 21 and second conductive traces 22 is provided, wherein the second conductive traces 22 are defined with a plurality of contact point areas 220.

In an embodiment, the contact point areas 220 are terminals of the second conductive traces 22.

As shown in FIG. 2B, a plurality of conductive pads 23 are formed on the contact point area 220, and the height h of each of the conductive pads 23 is greater than the height t of each of the first conductive traces 21.

In an embodiment, the conductive pads 23 are fabricated by deposition or electroplating.

Further, the first conductive trace 21 is formed between the conductive pads 23.

In an embodiment, the surfaces 21a of first conductive traces 21 and the surfaces of the second conductive traces 22 are flush with the surface 20a of the board 20. Alternatively, as shown in FIG. 2B′, through an etching process, the surfaces 21a′ of the first conductive traces 21′ and the surfaces of the second conductive traces 22 are lower than the surface 20a of the board 20, for example, about 0-10 μm lower than the surface 20a of the board 20.

As shown in FIG. 2C-2C″, an insulating protection layer 24 such as a solder mask layer is formed on the board 20, with the conductive pads 23 and a portion of the first and second conductive traces 21 and 22 exposed from the insulating protection layer 24 (as shown in FIG. 2C), and the conductive pads 23 and a portion of the second conductive traces 22 exposed from the insulating protection layer 24 (as shown in FIG. 2C″, through the insulating protection layer 24 covering the first conductive traces 21 to obtain a better isolation).

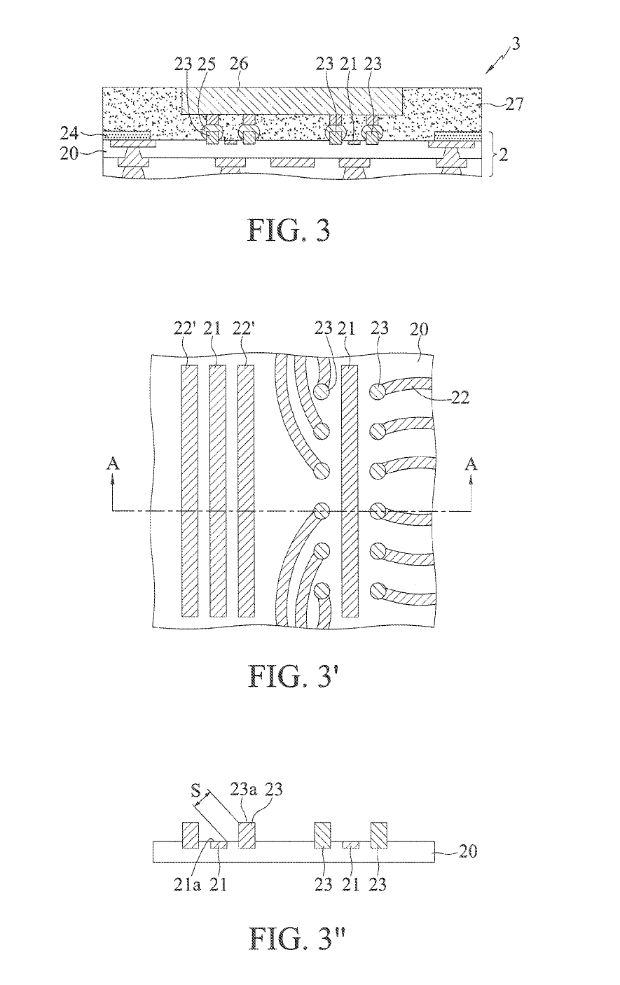

In the subsequent process, as shown in FIG. 3, an electronic component 26 is formed on and electrically connected to the conductive pads 23 via a plurality of conductive elements 25, such as solder bumps, in a flip-chip manner Subsequently, an encapsulating layer 27 is formed on the board 20 of the package substrate 2, and encapsulates the electronic component 26 and the conductive elements 25.

In an embodiment, the electronic component 26 is a passive component, an active component, or a combination of thereof, the active component can be a semiconductor chip, and the passive component can be a resistor, capacitor and inductor for instance.

In another embodiment, as shown in FIG. 3′, the second conductive traces 22′ are formed higher, and each has a height greater than the height of each of the first conductive traces 21, and a portion of each of the second conductive traces 22′ serves as a conductive pad 23.

In an embodiment, as the height h of each of the conductive pads 23 is greater than the height t of each of the first conductive traces 21, the path from the surface 23a (i.e. top surface) of the conductive pad 23 to the surface 21a of the first conductive trace 21 is a diagonal line S, as shown in FIG. 3″. As compared to the conventional horizontal line L, the diagonal line S has the length of about 31.5 nm, which is greater than the length 15 nm of the horizontal line L. Thus, when the electronic component 26 is disposed on the conductive pads 23, the conductive elements 25 would not make contact with the first conductive traces 21, thereby preventing the conductive pads 23 and the first conductive traces 21 from being shorted.

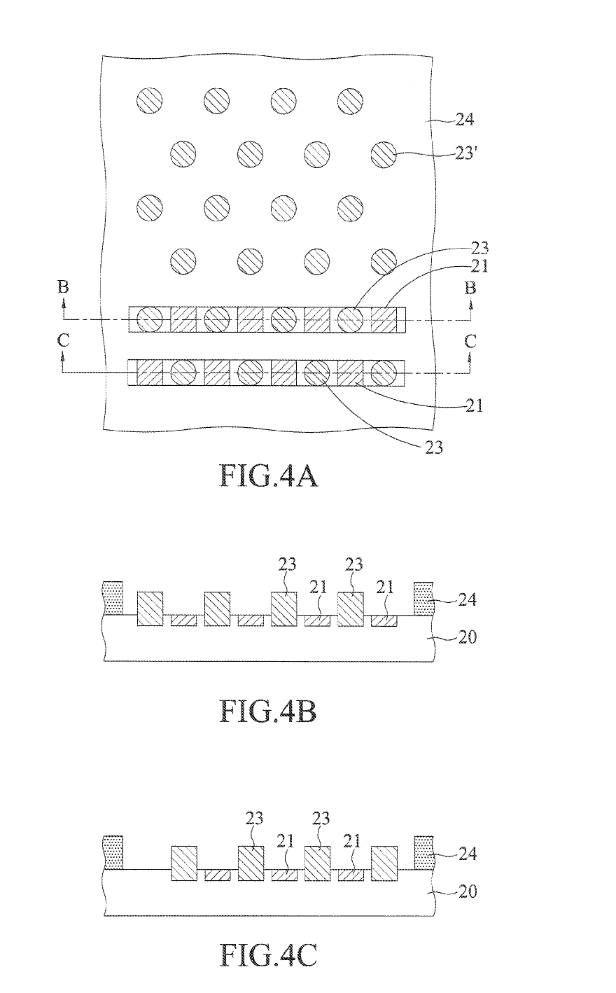

As shown in FIG. 4A-4C, the package substrate 2 has several rows of contact points, with the conductive pads 23 exposed from the insulating protection layer 24, and the first conductive traces 21 can be arranged in alternate ways.

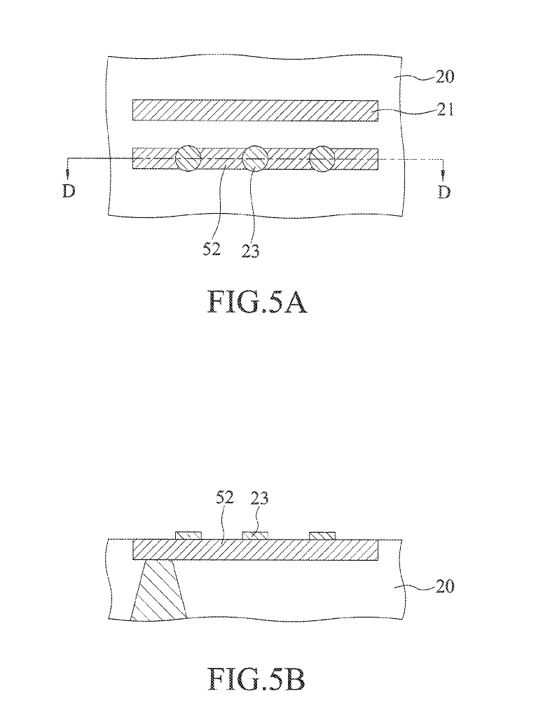

As shown in FIG. 5A-5B, the second conductive trace 52 is a power line or a grounding line, and more than one of the conductive pads 23 can be formed on one of the second conductive traces 52.

The present invention further provides a package structure 3, comprising: a package substrate 2, 2′, 2″, an electronic component 26 disposed on the package substrate 2, 2′, 2″, and an encapsulating layer 27 that encapsulates the electronic component 26.

The package substrate 2, 2′, 2″ comprises: a board 20, a plurality of first conductive traces 21, 21′ and a plurality of conductive pads 23 formed on the board 20, the conductive pads 23, each having a height t greater than the height t of each of the first conductive traces 21, 21′, and at least one of the conductive traces 21, 21′ is positioned in proximity of at least one of the conductive pads 23. The surfaces 21a and 21a′ of the first conductive traces 21 and 21′ are flush with or lower than the surface 20a of the board 20, and the surfaces 21a and 21a′ of the first conductive traces 21 and 21′ are exposed from the surface 20a of the board 20.

The electronic component 26 is disposed on and electrically connected to the conductive pads 23 via a plurality of conductive elements 25.

In an embodiment, the conductive pads 23 are formed on the contact point area 220 of the second conductive traces 22. For instance, more than one of the conductive pads 23 are formed on one of the second conductive traces 52.

In an embodiment, the package substrate 2, 2′, 2″ further comprises an insulating protection layer 24 formed on the board 20, with the conductive pads 23 exposed from the insulating protection layer 24.

In summary, the package structure and the method of fabricating the same according to the present invention are characterized by providing conductive pads formed on the package substrate to increase or reduce the height of the first conductive traces at the vicinity of the conductive traces, such that when the electronic components are disposed on the conductive pads, the conductive elements is prohibited to make contact with the first conductive traces, thereby solving the problem of short circuit resulted from bridging.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A package substrate, comprising:
a board having a plurality of conductive traces; and
a plurality of conductive pads formed on the board and each having a height greater than a height of each of the conductive traces,
wherein at least one of the conductive traces is positioned in proximity of at least one of the conductive pads.

2. The package substrate of claim 1, wherein the conductive traces have surfaces flush with or lower than a surface of the board.

3. The package substrate of claim 1, wherein each of the conductive traces has a surface exposed from a surface of the board.

4. The package substrate of claim 1, wherein the conductive pads are formed on the conductive traces.

5. The package substrate of claim 4, wherein more than one of the conductive pads are formed on one of the conductive traces.

6. The package substrate of claim 1, further comprising an insulating protection layer formed on the board, with the conductive pads exposed from the insulating protection layer.

7. A method of fabricating a package substrate, comprising:
providing a board having a plurality of conductive traces; and
forming on the board a plurality of conductive pads, each having a height greater than a height of each of the conductive traces,
wherein at least one of the conductive traces is positioned in proximity of at least one of the conductive pads.

8. The method of claim 7, wherein each of the conductive traces has a surface flush with or lower than a surface of the board.

9. The method of claim 7, wherein the conductive traces have surfaces exposed from a surface of the board.

10. The method of claim 7, wherein the conductive pads are formed on the conductive traces.

11. The method of claim 10, wherein more than one of the conductive pads are formed on one of the conductive traces.

12. The method of claim 7, further comprising forming an insulating protection layer on the board, with the conductive pads exposed from the insulating protection layer.

13. A package structure, comprising:
a board having a plurality of conductive traces;
a plurality of conductive pads formed on the board and each having a height greater than a height of each of the conductive traces; and
an electronic component disposed on and electrically connected to the conductive pads via a plurality of conductive elements,
wherein at least one of the conductive traces is positioned in proximity of at least one of the conductive pads.

14. The package structure of claim 13, wherein the conductive traces have a surface flush with or lower than a surface of the board.

15. The package structure of claim 13, wherein each of the conductive traces has a surface exposed from a surface of the board.

16. The package structure of claim 13, wherein the conductive pads are formed on the conductive traces.

17. The package structure of claim 16, wherein more than one of the conductive pads are formed on one of the conductive traces.

18. The package structure of claim 13, further comprising an insulating protection layer formed on the board, with the conductive pads exposed from the insulating protection layer.

19. The package structure of claim 13, further comprising an encapsulating layer that encapsulates the electronic component.

20. A method of fabricating a package structure, comprising:
forming a plurality of conductive pads on a board that has a plurality of conductive traces, wherein each of the conductive pads have a height greater than a height of each of the conductive traces, and at least one of the conductive traces is positioned in proximity of at least one of the conductive pads; and
disposing an electronic component on the conductive pads, and electrically connecting the electronic component to the conductive pads via a plurality of conductive elements.

21. The method of claim 20, wherein the conductive traces have surfaces flush with or lower than a surface of the board.

22. The method of claim 20, wherein the conductive traces have surfaces exposed from a surface of the board.

23. The method of claim 20, wherein the conductive pads are formed on the conductive traces.

24. The method of claim 23, wherein more than one of the conductive pads are formed on one of the conductive traces.

25. The method of claim 20, further comprising forming an insulating protection layer on the board, with the conductive pads exposed from the insulating protection layer.

26. The method of claim 20, further comprising forming on the board an encapsulating layer that encapsulates the electronic component.
